(19) United States
(12) Patent Application Publication
(10) Pub. No.: US 2017/0097398 A1
(43) Pub. Date: Apr. 6, 2017

(54) SHIMMING DEVICE FOR A MAGNETIC RESONANCE IMAGING APPARATUS WITH ENHANCED COOLING AND METHOD FOR PROVIDING SUCH A DEVICE

(71) Applicant: SIEMENS HEALTHCARE LIMITED, CAMBERLEY (GB)

(72) Inventor: Marcel Kruip, Oxford (GB)

(73) Assignee: SIEMENS HEALTHCARE LIMITED, CAMBERLEY (GB)

(21) Appl. No.: 15/128,270

(22) PCT Filed: Mar. 2, 2015
(86) PCT No.: PCT/EP2015/054316

§ 371 Date: Sep. 22, 2016

(30) Foreign Application Priority Data
Mar. 24, 2014 (GB) 1405196.5

(51) Int. Cl. G01R 33/3873; G01R 33/38

(52) U.S. Cl. CPC G01R 33/3873; G01R 33/3804

(57) ABSTRACT

The invention concerns a device for shimming the magnetic field of a magnetic resonance imaging apparatus, having an outer vacuum chamber bore tube (1), whereby at the outer vacuum chamber bore tube (1) a retaining element (2) is mounted, whereby in the space (6) between the retaining element (2, 3) and the outer vacuum chamber bore tube (1) at least one shim assembly (7) and at least one hose element (8), which is filled or can be filled with a cooling fluid, are arranged.

### BACKGROUND OF THE INVENTION

Field of the Invention

The present invention concerns a shimming device for shimming the basic magnetic field in a magnetic resonance imaging apparatus.

Description of the Prior Art

In magnetic resonance imaging apparatuses, the homogeneity and the stability of the basic magnetic field is of high relevance for the quality of the measurement. To improve the homogeneity, so-called ‘shimming’ of the magnetic field is used. Passive shimming involves pieces of steel with good magnetic qualities. The steel pieces are placed near the permanent or superconducting magnet. They get magnetized and produce their own magnetic field. The additional magnetic fields produced by the steel pieces, which are often called shims or shim elements, add to the overall magnetic field of the superconducting magnet in such a way that the total field becomes more homogeneous.

It is known that an increase of the temperature of the outer vacuum chamber bore tube and of the shims can cause a drift of the magnetic field in the magnetic resonance imaging apparatus.

US 2010/0225321 teaches tubes filled with liquid or gas to damp the noise caused by the movement of gradient coils in a magnetic resonance imaging apparatus. These tubes, to be more exact the fluid in the tubes, can also be used for cooling the gradient coils.

Shimming arrangements are described in US2003/206018, U.S. Pat. No. 6,313,634, JP2012-011060, U.S. Pat. No. 4,983,942, US2004/032263.

### SUMMARY OF THE INVENTION

An object of the invention is to provide an improved mechanism for stabilizing the magnetic field in a magnetic resonance imaging apparatus.

According to an aspect of the present invention, a device is provided for shimming the magnetic field of a magnetic resonance imaging apparatus having an outer vacuum chamber bore tube, wherein a retaining element is mounted at the outer vacuum chamber bore tube. At least one shim assembly and at least one hose, element or bladder, which is filled or can be filled with a cooling fluid, are arranged in a space between the retaining element and the outer vacuum chamber bore tube.

The hose or bladder may be filled with a cooling fluid, which may for example be cooled in a cooling loop arrangement such that the shim assembly and the outer vacuum chamber bore tube may thereby both have good thermal contact to the cooling system comprising the hose element or bladder. For avoiding of misunderstandings, of course the cooling effect is only possible if the hose element or bladder is indeed filled with the cooling fluid.

The filled hose element also can induce a very tight-fitting arrangement of the hose element, the shim assembly and the retaining element and the outer vacuum chamber bore tube.

So the shim assembly is secured in place. In some arrangements, the individual shim elements may be held in place by the hose element or bladder. This is of relevance as significant forces can act on the shim elements in use. For example the radial force on a shim stack of 5 mm height can be in the order of 300 N.

The tight-fitting arrangement of hose or bladder, shim assembly and retaining element also provides good thermal contact between the outer vacuum chamber bore tube, the shim assembly and the retaining element and the hose element or bladder. Heat can therefore readily be transferred to the cooling fluid in the hose element or bladder.

As will be explained below in more detail, certain embodiments of the invention do not provide the retaining element or the outer vacuum chamber bore with direct contact to the hose element or bladder. Nevertheless, in a tight-fitting arrangement a good thermal contact can also be possible if for example the heat from the outer vacuum chamber has to be transferred through the shim assembly or retaining element to cooling fluid in the hose element or bladder.

Moreover the device also has to effect to dampen noise in a similar manner as is known from US 2010/0225321.

The most important example for the cooling fluid is surely water, as water has a high specific heat, is non-toxic and cheap. Nevertheless a lot of other cooling fluids also can be used.

In an embodiment of the invention the retaining element is a clamp, especially a U-shaped clamp. A clamp is suited to hold the hose element or bladder and the shim assembly together. It is to note that the retaining element has to resist significant forces, because significant forces act on the shim elements in the shim assembly in use. The filled hose element or bladder also causes further forces to act on the retaining element, as pressure of fluid within the filled hose element or bladder may provide further forces tending to separate the shim assembly, the retaining element and the outer vacuum chamber bore tube.

In an embodiment of the invention the retaining element is welded to the outer vacuum chamber bore tube. Welding allows a very stable mounting of the retaining element, which can be realized in a simple manner, and provides thermal conduction between the retaining element and the outer vacuum chamber bore tube.

In an alternative embodiment of the invention, the retaining element is made of a non-electrically conducting material. This is advantageous with respect to the shimming function of the shimming assembly, as no complexity is introduced by the possibility of electric currents flowing in the retaining element.

In an embodiment of the invention, the hose element is flat when it is unfilled. This allows using a so called “Layflat” hose, which is well known and available. A layflat hose is easier to install than a hose of fixed external dimensions. An alternative is a thermally welded polyethylene bladder. In such arrangements, the hose element or bladder is distensible, expanding on introduction of a fluid. The expanding hose element of bladder enables the hose element or bladder to adapt to the shape of the shim assembly, retaining element and/or outer vacuum container bore tube to provide effective thermal contact and mechanical pressure on such elements.

In a further embodiment of the invention, the hose element is a PVC-hose. PVC-hoses are widely available and are flexible. This flexibility renders the hose distensible to a certain extent, which allows an increase of the volume of the hose element when it is filled with cooling fluid.

In an embodiment of the invention the hose element is a hose with a wall thickness of about 1 mm. Such a PVC-hose has been found to have a sufficient mechanical stability, and the thermal characteristics tend to be expedient. The thermal conductivity of PVC is about 0.2 W/mK. So a PVC-hose wall with a width of 50 mm and 1 m length can lead away a heat load of 1W, if the temperature difference is 0.1 K.

In embodiments of the invention, the shim assembly is arranged facing the outer vacuum chamber bore tube or the retaining element at a first side and facing the hose element or bladder at a second side.

There are alternative possible arrangements of the shim assembly and the hose element or bladder in the space between the retaining element and the outer vacuum chamber bore tube. Two of them are of major relevance: firstly, the shim assembly may be arranged facing the outer vacuum chamber bore tube on a first side; on a second side the hose element is attached, such that the hose element is arranged between the shim assembly and the retaining element. Another alternative is to arrange the hose element facing the outer vacuum chamber bore tube, such that the shim assembly is arranged between the hose element and the retaining element.

More than one hose element may be provided, so it would be possible to arrange one hose element facing the outer vacuum chamber bore tube and another hose element facing the retaining element, such that the shim assembly can be placed between the hose elements.

In an embodiment of the invention, the hose element or bladder can be filled with the cooling fluid after it is positioned in place, so that the hose element or bladder is pressed onto adjacent surfaces of the shim assembly and the retaining element and/or the outer vacuum chamber bore tube. So the hose element can easily be inserted in the space between the shim assembly and the retaining element and/or the outer vacuum chamber bore tube. After inserting the hose element or bladder, it can be filled with the cooling fluid and care for the tight-fitting arrangement as explained above.

In a further embodiment of the invention the shim assembly is a single shim element or a shim tray containing several shim elements. The shim elements typically have a dimension of 80 mm by 65 mm. The shim tray allows a compact arrangement of several shim elements, so a good thermal contact can be achieved. As is conventional it itself, the shim elements can be retained in the shim tray by sticky tape or similar, to prevent the shim elements falling out of the shim tray.

In certain embodiments of the invention, the cooling fluid can flow through a cooler. In the cooler the heat transferred to the cooling fluid from the shim assembly and/or the outer vacuum container bore tube can be removed, for example by dissipation or refrigeration. The cooling fluid is thereby cooled and can be returned to the hose element again in a cooling loop arrangement. In most cases the cooler is a heat exchanger, in which the heat of the cooling fluid is transferred to another fluid or to ambient. In other embodiments of the invention, the thermal mass of the cooling fluid is high enough to essentially stabilize the temperature of the outer vacuum chamber bore tube and the shim assembly without further cooling of the cooling fluid. In this case a cooler as described above is not necessary.

Of course both approaches, cooling the cooling fluid in a cooler and providing a high thermal mass can be combined. For providing a high thermal mass a suitable cooling fluid, for example water should be used. Furthermore the hose element should have a sufficient dimension to contact the shim assembly and the outer vacuum container bore tube or retaining member. Also an external reservoir for the cooling fluid can increase the thermal mass of the cooling fluid. The advantage of a high thermal mass is a self-stable mechanism, such that no control system, or only a simple control system is needed. If the dimension of the hose element is high enough, even pumping of the cooling fluid around the hose elements may be found unnecessary.

The present invention also encompasses a method for providing a device for shimming a magnetic field of a magnetic resonance imaging apparatus, wherein: A hose element is inserted in a space between an outer vacuum chamber bore tube and a retaining element, whereby the hose element is filled with a cooling fluid after inserting in the space. This allows inserting the hose element in a simple manner. A tight-fitting arrangement with good thermal contact to the cooling fluid can be achieved by filling the hose element with the cooling fluid. This method is especially useful for providing a device as presented above.

### BRIEF DESCRIPTION OF THE DRAWINGS

FIG. 1 shows an outer vacuum chamber bore tube with a retaining element wherein, in the space between the retaining element and the outer vacuum chamber bore tube, a shim assembly facing the outer vacuum bore tube and a hose element are arranged.

FIG. 2 shows an arrangement like FIG. 1, whereby the hose element faces the outer vacuum chamber bore tube.

FIG. 3 shows a three-dimensional cutaway of FIG. 2.

### DESCRIPTION OF THE PREFERRED EMBODIMENTS

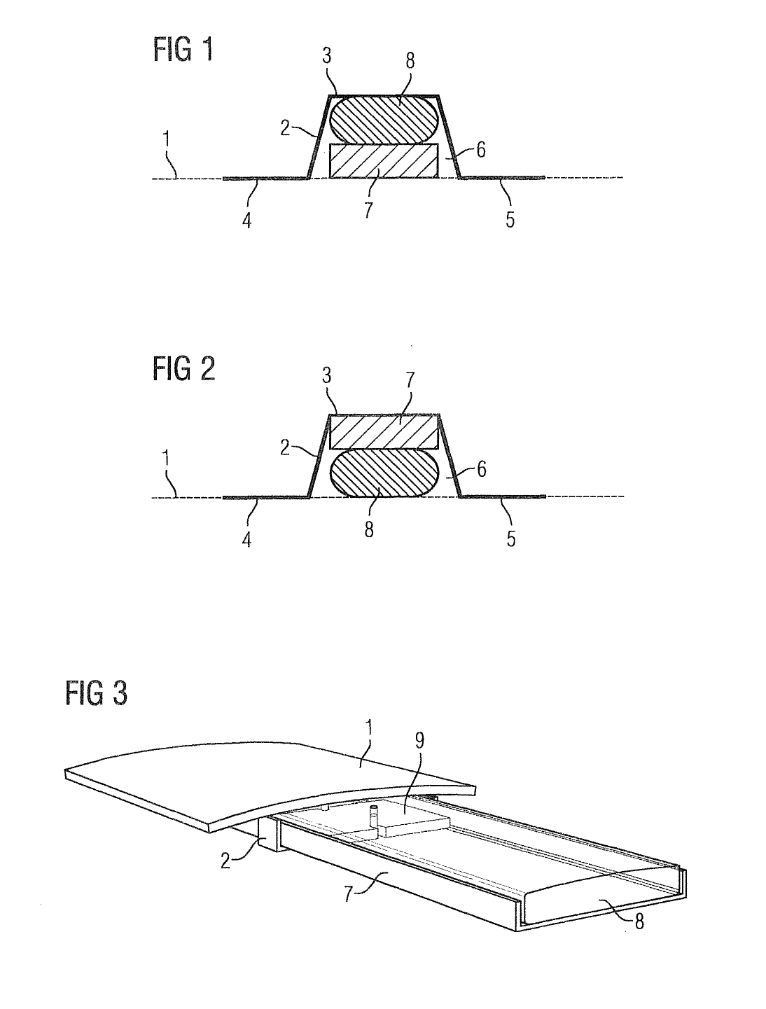

The dotted line in FIG. 1 schematically represents an outer vacuum chamber bore tube 1 of a magnetic resonance imaging apparatus, which is not itself shown. A retaining element is provided, in this case in the form of retaining clamp 2. As shown in the drawing, the retaining clamp 2 has a U-shaped section 3. Retaining clamp 2 also comprises interface sections 4 and 5, which face and join the outer vacuum chamber bore tube 1. The interface sections 4 and 5 of the retaining clamp 2 and the outer vacuum chamber bore tube 1 may be welded together, providing a very stable connection between the retaining clamp 2 and the outer vacuum chamber bore tube 1. Other methods for attaching the retaining element 2 and the outer vacuum container bore tube 1 may be used instead, as will be apparent to those skilled in the art.

The outer vacuum chamber bore tube is in fact cylindrical, and multiple sets of retaining element 2/hose element or bladder 8/shim assembly 7 may be provided around the cylindrical surface of the outer vacuum container bore tube. Due to the heating involved, and the presence of a cooling fluid, the sets of retaining element 2/hose element or bladder 8/shim assembly 7 are preferably provided on the non-vacuum side of the OVC, at approximately ambient temperature and pressure. It may, however, be possible to provide the sets of retaining element 2/hose element or bladder 8/shim assembly 7 on the vacuum side of the outer vacuum container bore tube.

The U-shaped section 3 of the retaining element 2 and the outer vacuum chamber bore tube 1 define a space 6 between. A shim assembly 7 comprising a shim tray and shim elements (not themselves visible in FIG. 1) is arranged in the space 6. The shim assembly 7 is located between the outer vacuum chamber bore tube 1 and a hose element 8, which is itself located between the shim assembly 7 and the U-shaped section 3.

After assembly, the hose element 8 is filled with water as a cooling fluid. The hose element 8 then expands and is pressed to the U-shaped section 3 on one side and to the shim assembly 7 on the other side. A tight-fitting arrangement is thereby achieved, which ensures good thermal contact between the hose element 8 and the U-shaped section 3 on the one side to the shim assembly 7 on the other side.

In some embodiments, the hose 8 is a layflat hose, which is placed in position in a flattened state and which fills with water and expands into contact with the U-shaped section and the shim assembly 7. In others, the hose is distensible, meaning that it continues to expand as a pressure of the cooling water inside it increases. In each case, the holes element may be replaced by a bladder in respect of at least one of the shim assemblies.

In the embodiment according to FIG. 1 there is no direct contact of the hose element 8 to the outer vacuum chamber bore tube 1. Due to the good thermal contact of the outer vacuum chamber bore tube 1 to the shim assembly 7 and the retaining clamp 2, heat can flow through the shim assembly 7 and/or the retaining clamp 2 to the hose element 8.

FIG. 2 illustrates a similar view of an alternative embodiment. In the embodiment of FIG. 2, the hose element 8 contacts the outer vacuum chamber bore tube 1 and the shim assembly 7. The shim assembly 7 is itself placed between hose element 8 and the U-shaped section 3. In this embodiment, there is a direct thermal contact between the outer vacuum chamber bore tube 1 and the hose element 8.

FIG. 3 shows the embodiment of FIG. 2 in a three-dimensional cutaway. The curvature of the outer vacuum container bore tube 1 is visible. The retaining clamp 2 retains the shim tray 7 on the non-vacuum side of the outer vacuum container bore tube 1. Within the shim assembly 7 a shim stack 9 is arranged in contact to the hose element 8. In this arrangement, the hose 8 protrudes into a recess in the shim tray, and moulds itself around any shim stacks 9. The hose element of this embodiment may be said to be “integrated” into the shim assembly 7. In other embodiments (not shown), the shim tray may be enclosed, or inverted, such that the hose does not protrude into the shim tray.

Connecting tubes (not illustrated) may be provided to allow circulation of cooling fluid through the hose elements. In other embodiments, some or all of the hose elements may be replaced by a distensible bladder. Connecting tubes may be provided to allow circulation of cooling fluid through those bladders. Alternatively, the bladders may each be sealed where the mass of cooling fluid in each bladder is found sufficient to impart the required thermal stability.

Although the invention has been explained in more detail by means of the exemplary embodiments, the invention shall not be restricted be the disclosed examples. Other variations can be found by a man skilled in the art without leaving the scope of protection as defined by the appended claims.

1. (canceled)

2. Device according to claim 14 wherein the retaining element is a U-shaped clamp.

3. Device according to claim 14 wherein the retaining element is welded to the outer vacuum chamber bore tube.

4. Device according to claim 14 wherein the retaining element is made of a non-electrical conducting material.

5. Device according to claim 14 wherein the distensible fluid-containing vessel is flat when it is unfilled.

6. Device according to claim 14 wherein the distensible fluid-containing vessel is a PVC-hose.

7. Device according to claim 14 wherein the distensible fluid-containing vessel is a hose with a wall thickness of about 1 mm.

8. Device according to claim 14 wherein the distensible fluid-containing vessel is fillable with the cooling fluid after insertion thereof in the space, so that the distensible fluid-containing vessel is pressed into contact with the shim assembly and the retaining element or the outer vacuum chamber bore tube.

9. Device according to claim 14 wherein the shim assembly is a single shim element or a shim tray containing several shim elements.

10. Device according to claim 14 comprising multiple sets of said retaining element, said distensible fluid-containing vessel, and said shim assembly, each set being on a surface of the outer vacuum container bore tube, and connecting tubes linking the distensible fluid-containing vessel in each set to a cooler for cooling the cooling fluid.

11. Device according to claim 14 wherein the cooling fluid has a thermal mass that stabilizes a temperature of the outer vacuum chamber bore tube and the shim assembly.

12. Device according to claim 11, wherein said distensible fluid-containing vessel is a bladder, filled with the cooling fluid and sealed to prevent egress of the cooling fluid from the bladder.

13. (canceled)

14. A device for shimming a basic magnetic field of a magnetic resonance imaging apparatus, said magnetic resonance imaging apparatus having an outer vacuum chamber bore tube, said device comprising:
a retaining element mounted at said outer vacuum chamber bore tube so as to produce a space between said retaining element and said outer vacuum chamber bore tube;
at least one shimming assembly situated in said space configured to shim a basic magnetic field of said magnetic resonance imaging apparatus;
at least one distensible fluid-containing vessel also situated in said space, said at least one distensible fluid-containing vessel being Tillable with a cooling fluid and comprising a vessel wall that expands upon introduction of the cooling fluid into said at least one distensible fluid-containing vessel; and
said at least one distensible fluid-containing vessel and said at least one shim assembly being situated in said space, with said at least one distensible fluid-containing vessel being situated between said at least one shim assembly and the outer vacuum bore tube, or between said at least one shim assembly and said retaining element, with said shim assembly having a first side adjacent the outer vacuum bore tube or the retaining element, and having a second side adjacent said at least one distensible fluid-containing vessel.

15. A method for shimming a basic magnetic field of a magnetic resonance imaging apparatus, said magnetic resonance imaging apparatus having an outer vacuum chamber bore tube, said method comprising:
attaching a retaining element to said outer vacuum chamber bore tube so as to produce a space between said retaining element and said outer vacuum chamber bore tube;
providing at least one shimming assembly in said space configured to shim a basic magnetic field of said magnetic resonance imaging apparatus;
also providing at least one distensible fluid-containing vessel in said space, and filling said at least one distensible fluid-containing vessel with a cooling fluid that causes a vessel wall of said at least one distensible fluid-containing vessel to expand upon introduction of the cooling fluid into said at least one distensible fluid-containing vessel; and
situating said at least one distensible fluid-containing vessel and said at least one shim assembly being in said space, with said at least one distensible fluid-containing vessel being situated between said at least one shim assembly and the outer vacuum bore tube, or between said at least one shim assembly and said retaining element, with said shim assembly having a first side adjacent the outer vacuum bore tube or the retaining element, and having a second side adjacent said at least one distensible fluid-containing vessel.
